(19) United States
(12) Patent Application Publication
(10) Pub. No.: US 2020/0274013 A1
(43) Pub. Date: Aug. 27, 2020

(54) SOLAR MODULE FOR MOUNTING ON A SURFACE

(71) Applicant: Southern Taiwan University of Science and Technology, Tainan City (TW)

(72) Inventor: Ruei-Tang Chen, Tainan City (TW)

(21) Appl. No.: 16/508,394

(22) Filed: Jul. 11, 2019

(30) Foreign Application Priority Data
Feb. 21, 2019 (TW) 108105751

(51) Int. Cl. H01L 31/054; H01L 31/048; H01L 31/052

(52) U.S. Cl. CPC H01L 31/054; H02S 20/24; H01L 31/052; H01L 31/048

(57) ABSTRACT

A solar module includes a substrate, a light permeable cover plate, a cell layer, an encapsulate layer and a heat-insulation space. The light permeable cover plate faces a light entry surface of the substrate. The cell layer includes a plurality of solar cells disposed between the substrate and the light permeable cover plate. A total area of the solar cells is smaller than a total area of the substrate. The encapsulation layer is disposed between the substrate and the light permeable cover plate, and encapsulates the solar cells. The heat-insulation space is disposed either between the light permeable base plate and the first diffusion film or between the substrate and the cell layer.

### CROSS-REFERENCE TO RELATED APPLICATION

This application claims priority to Taiwanese Patent Application No. 108105751, filed on Feb. 21, 2019.

### FIELD

The disclosure relates to a solar module, and more particularly to a solar module that is light permeable and that is suitable for mounting on a roof and wall of a building surface.

### BACKGROUND

A conventional solar module includes a plurality of solar cells arranged in rows and columns to convert solar energy into electrical energy. The conventional solar module is commonly used on a greenhouse roof to provide electric power. Because the conventional solar module is partially light permeable, outdoor light rays can pass through the conventional solar module to irradiate the inside of the greenhouse, thereby helping plant growth. Besides, the conventional solar module may be mounted on a roof or wall of a building such as a farmhouse, a residential house, a church, a business building, a bus station, etc.

However, because the solar cells are usually light impermeable, the profiles of the solar cells are conspicuous and less aesthetic when being viewed from the inside of the building. Further, the indoor temperature is raised when sun light rays pass through the conventional solar module into the inside of the building.

### SUMMARY

Therefore, an object of the disclosure is to provide a solar module that can alleviate at least one of the drawbacks of the prior art.

According to the disclosure, a solar module for mounting on a surface includes a substrate, a light permeable cover plate, a cell layer, an encapsulation layer and a heat-insulation space.

The substrate includes a light permeable base plate that has a light entry surface and a light exit surface opposite to the first light entry surface, and a first diffusion film that is disposed on one of the light entry surface and the light exit surface for scattering light rays evenly.

The light permeable cover plate faces the light entry surface.

The cell layer includes a plurality of solar cells disposed between the substrate and the light permeable cover plate. A total area of the solar cells is smaller than a total area of the substrate.

The encapsulation layer is disposed between the substrate and the light permeable cover plate, and encapsulates the solar cells.

The heat-insulation space is disposed either between the light permeable base plate and the first diffusion film or between the substrate and the cell layer.

### BRIEF DESCRIPTION OF THE DRAWINGS

Other features and advantages of the disclosure will become apparent in the following detailed description of the embodiments with reference to the accompanying drawings, of which:

FIG. 1 is a perspective view illustrating a building with a roof composed of solar modules according to the disclosure;

FIG. 2 is a fragmentary sectional view of a first embodiment of a solar module according to the disclosure;

FIG. 3 is a fragmentary sectional view illustrating a second embodiment of the solar module according to the disclosure;

FIG. 4 is a fragmentary sectional view illustrating a third embodiment of the solar module according to the disclosure;

FIG. 5 is a fragmentary sectional view illustrating a fourth embodiment of the solar module according to the disclosure; and

FIG. 6 is a fragmentary sectional view illustrating a fifth embodiment according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

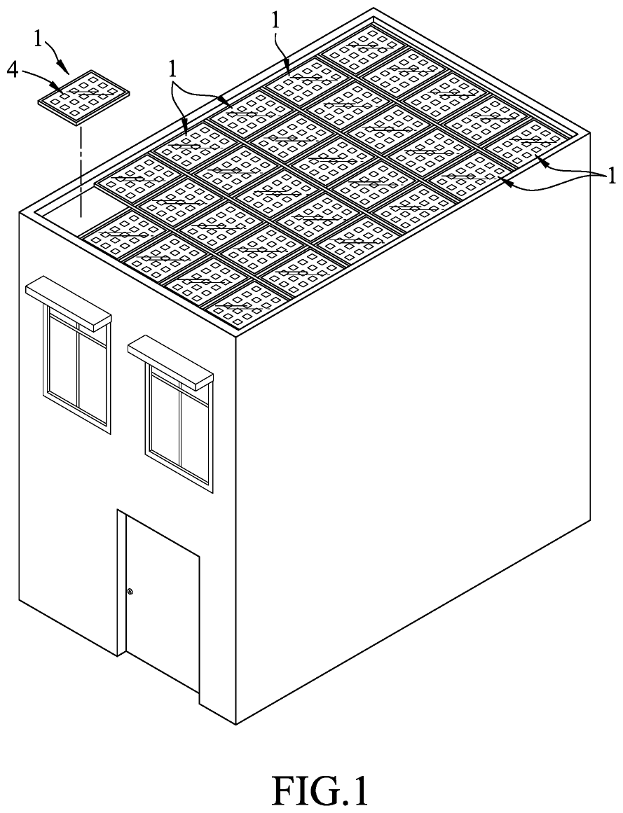

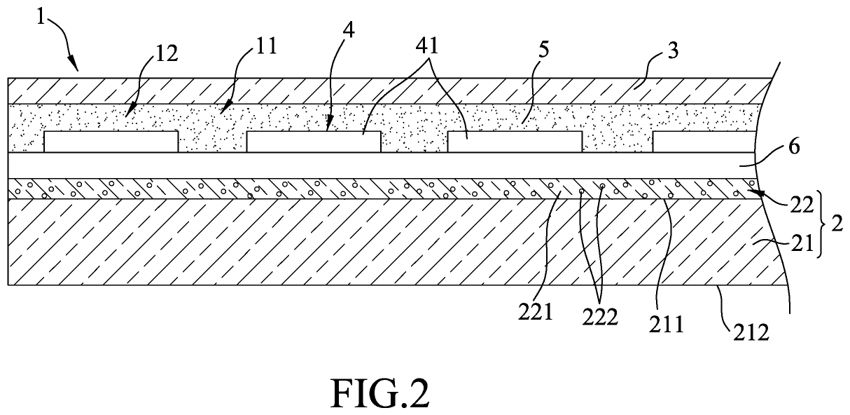

FIG. 1 illustrates a roof of a building composed of a plurality of solar modules 1 which are mounted in juxtaposition with each other on the building. The building can be, but not limited to, a greenhouse, a farmhouse, a residential house or a bus station. Referring to FIG. 2, a solar module 1 according to a first embodiment of the disclosure is shown, which includes a substrate 2, a light permeable cover plate 3, a cell layer 4, an encapsulation layer 5 and a heat-insulation space 6.

The substrate 2 includes a light permeable base plate 21 that has a light entry surface 211 and a light exit surface 212 opposite to the first light entry surface 211, and a first diffusion film 22 that is disposed on the light entry surface 211. The light permeable base plate 21 is, for example, a light permeable plastic film substrate or a glass substrate. The light entry surface 211 faces outwardly of the building. The light exit surface 212 faces the inside of the building. The first diffusion film 22 is used for scattering light rays evenly. The first diffusion film 22 has a film body 221 and a plurality of light scattering particles 222 distributed within the film body 221. The film body 221 is made of, for example, polyethylene terephthalate or polycarbonate. The light scattering particles 222 can be, for example, BaSO₄, TiO₂ or Polystyrene particles.

The light permeable cover plate 3 faces the light entry surface 211, and is a light permeable glass plate with a thickness smaller than 1 mm.

The cell layer 4 includes a plurality of solar cells 41 disposed and arranged in rows and columns between the first diffusion film 22 and the light permeable cover plate 3. A total area of the solar cells 41 is smaller than a total area of the light permeable base plate 21. Therefore, the solar module 1 provides a light permeable area 11 that allows light rays to pass through two adjacent ones of the solar cells 41, and a light impermeable area 12 that is occupied by the solar cells 41. Each solar cell 41 is a crystalline silicon cell or a thin film solar cell.

The encapsulation layer 5 is disposed between the substrate 2 and the light permeable cover plate 3, and encapsulates the cell layer 4. The encapsulation layer 5 fixes the solar cells 41 between the substrate 2 and the light permeable cover plate 3. The encapsulation layer 5 is made from ethylene vinyl acetate (EVA).

The heat-insulation space 6 is formed between the first diffusion film 22 and the cell layer 4. The heat-insulation space 6 has a thickness in range between 0.1 cm and 10 cm. In addition, the head-insulation space 6 is filled with a gaseous substance selected from air, at least one of or a mixture of nitrogen, argon, helium, and neon, and a mixture of nitrogen and oxygen.

In use, external light rays, such as sunlight rays, pass in a sequential manner through the light permeable cover plate 3, the encapsulation layer 5, the heat-insulation space 6, the first diffusion film 22 and the light permeable base plate 21 to irradiate the inside of the building, so that the inside of the building is appropriately brightened. Because the first diffusion film 22 diffuses the external light rays evenly, the light rays passing through the first diffusion film 22 are scattered beneath the solar cells 41. Therefore, indoor regions of the building beneath both of the light permeable area 11 and the light impermeable permeable area 12 can be irradiated evenly. By virtue of the first diffusion film 22, profiles of the solar cells 41 are blurred and modified. When the solar module 1 is viewed from the inside of the building, the solar module 1 has an even brightness and the profiles of the solar cells 41 are inconspicuous, thereby providing better visual aesthetics. Because the heat transfer coefficient of gas is lower than that of a solid material, the gaseous substance filled within the head-insulation space 6 can alleviate heat conduction to reduce heat of sun light rays entering the interior space of the building through the solar cells 41.

If the thickness of the heat-insulation space 6 is too thin, the thermal insulation is poor. If the thickness of the heat-insulation space 6 is too thick, the solar module 1 has an excessive thickness. Preferably, the thickness of the heat-insulation space 6 is to range from 0.1 cm to 10 cm. In addition, a framing member (not shown) may be disposed between and fixed to edges of the cell layer 4 and the substrate 2 by adhesive bonding so that the heat-insulation space 6 is sealed between the substrate 2 and the cell layer 4. The total area of the solar cells 41 preferably ranges from 10 percent to 91 percent of the total area of the substrate 2, so that the light permeable area 11 is sufficient to irradiate light rays into the interior space of the building.

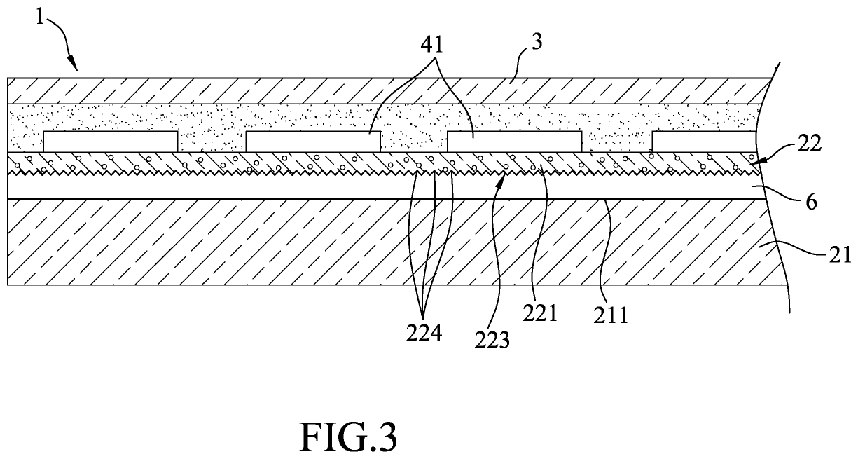

FIG. 3 illustrates a second embodiment of the solar module 1 according to the disclosure, which has a structure generally similar to that of the first embodiment. However, in this embodiment, the solar cells 41 are disposed in contact with the first diffusion film 22. The first diffusion film 22 is disposed on and spaced apart from the light entry surface 211 of the light permeable base plate 21. The heat-insulation space 6 is formed between the light entry surface 211 and the first diffusion film 22 to prevent the heat energy from entering the interior space of the building. Further, the film body 221 of the first diffusion film 22 has a structure surface 223 facing the light permeable base plate 21. The structure surface 223 has a plurality of microstructures 224 for scattering light rays. By virtue of the microstructures 224 reflecting light rays, the first diffusion film 22 is more effective to scatter the light rays evenly into the interior space of the building and to blur the profiles of the solar cells 41. In addition, the microstructures 224 can also be applied to the first embodiment.

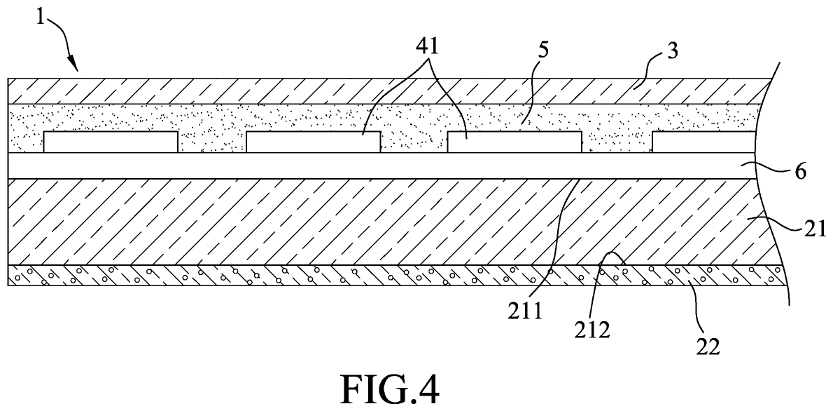

FIG. 4 illustrates a third embodiment of the solar module 1 according to the disclosure, which has a structure generally similar to that of the first embodiment. However, in this embodiment, the first diffusion film 22 is disposed on the light exit surface 212 of the light permeable base plate 21 and faces inside of the housing. The heat-insulation space 6 is formed between the light entry surface 211 of the light permeable base plate 21 and the cell layer 4. The cell layer 4 is fixed to the light permeable cover plate 3 by the encapsulation layer 5. The assembly of the cell layer 4, the encapsulation layer 5 and the light permeable cover plate 3 is fixed to the light permeable base plate 21 by adhesively bonding a frame (not shown) to the edge of the light permeable base plate 21 for sealing the heat-insulation space 6.

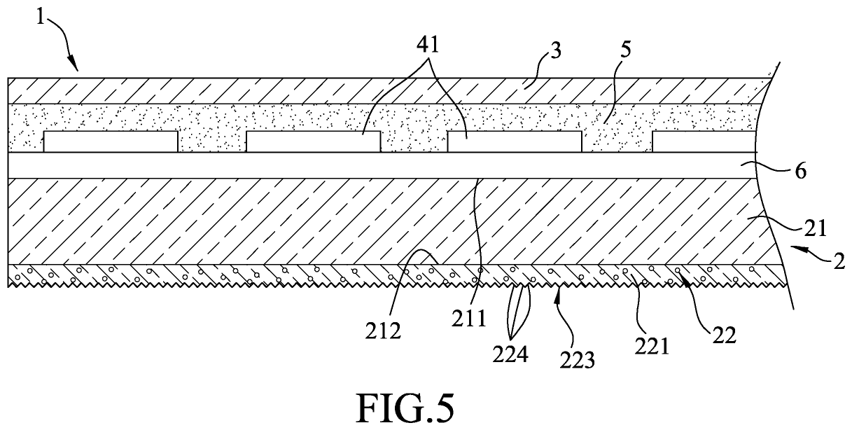

FIG. 5 illustrates a fourth embodiment of the solar module 1 according to the disclosure, which has a structure generally similar to that of the third embodiment. However, in this embodiment, the film body 221 of the first diffusion film 22 has a structure surface 223 disposed oppositely of the light permeable base plate 21. The structure surface 223 has a plurality of microstructures 224 for scattering light rays.

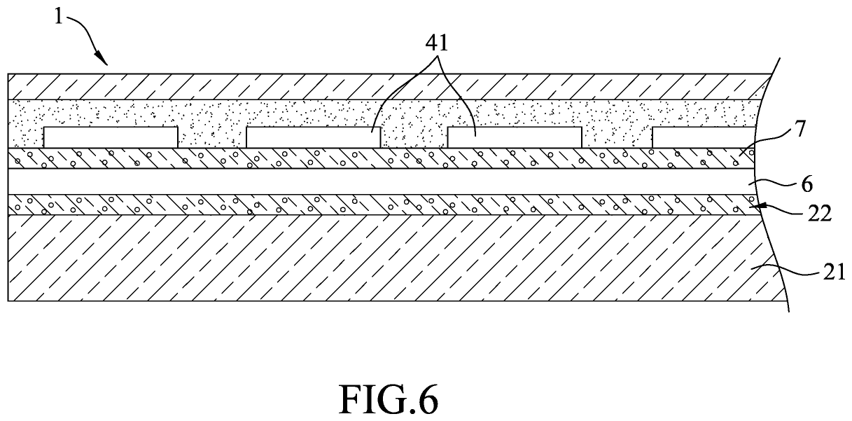

FIG. 6 illustrates a fifth embodiment of the solar module 1 according to the disclosure, which has a structure generally similar to that of the first embodiment. However, in this embodiment, the solar module 1 further includes a second diffusion film 7 disposed between the cell layer 4 and the heat-insulation space 6. The second diffusion film 7 is substantially identical in material and structure to the first diffusion film 22. The second diffusion film 7 is capable of scattering light rays evenly. By virtue of the second diffusion film 7 scattering light rays evenly, the solar module 1 emits light more uniformly. In addition, each of the first and second diffusion films 22, 7 can also has the microstructures 224 (see FIG. 3).

In summary, by virtue of the first diffusion film 22 disposed on one of the light entry surface 211 and the light exit surface 212 of the light permeable base plate 21, light rays are uniformly scattered and the profiles of the solar cells 41 are blurred. The number of the diffusion films may be increased. The provision of the second diffusion film 7 (see FIG. 6) scatter light rays more uniformly. The heat-insulation space 6 can reduce heat entering the interior space of the building from sunlight and the solar cells 41.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

1. A solar module for mounting on a surface, comprising:
a substrate including a light permeable base plate that has a light entry surface and a light exit surface opposite to said first light entry surface, and a first diffusion film that is disposed on one of said light entry surface and said light exit surface for scattering light rays evenly;
a light permeable cover plate facing said light entry surface;
a cell layer including a plurality of solar cells disposed between said substrate and said light permeable cover plate, a total area of said solar cells being smaller than a total area of said substrate;
an encapsulation layer disposed between said substrate and said light permeable cover plate, and encapsulating said solar cells; and
a heat-insulation space disposed either between said light permeable base plate and said first diffusion film or between said substrate and said cell layer.

2. The solar module as claimed in claim 1, wherein said heat-insulation space has a thickness in range between 0.1 cm and 10 cm.

3. The solar module as claimed in claim 2, wherein said heat-insulation space is filled with a gaseous substance selected from air, at least one of or a mixture of nitrogen, argon, helium, and neon, and a mixture of nitrogen and oxygen.

4. The solar module as claimed in claim 1, wherein said first diffusion film is disposed on said light entry surface of said light permeable base plate, said heat-insulation space being formed between said first diffusion film and said cell layer.

5. The solar module as claimed in claim 4, wherein said first diffusion film having a structure surface facing said light permeable base plate, said structure surface having a plurality of microstructures for scattering light rays.

6. The solar module as claimed in claim 1, wherein said first diffusion film is disposed on said light entry surface of said light permeable base plate, said heat-insulation space being formed between said light entry surface and said first diffusion film.

7. The solar module as claimed in claim 6, wherein said first diffusion film having a structure surface facing said light permeable base plate, said structure surface having a plurality of microstructures for scattering light rays.

8. The solar module as claimed in claim 1, wherein said first diffusion film is disposed on said light exit surface of said light permeable base plate, said heat-insulation space being formed between said light entry surface of said light permeable base plate and said cell layer.

9. The solar module as claimed in claim 8, wherein said first diffusion film having a structure surface, said structure surface having a plurality of microstructures for scattering light rays.

10. The solar module as claimed in claim 4, further comprising a second diffusion film disposed between said cell layer and said heat-insulation space, said second diffusion film being capable of scattering light rays evenly.
